(19) United States
(12) Patent Application Publication
(10) Pub. No.: US 2011/0037811 A1
(43) Pub. Date: Feb. 17, 2011

(54) LIQUID EJECTING HEAD AND LIQUID EJECTING APPARATUS USING THE SAME

(75) Inventor: Xiaoxing WANG, Chino-shi (JP)

Correspondence Address: WORKMAN NYDEGGER;1000 Eagle Gate Tower, 60 East South Temple, Salt Lake City, UT, 84111, US

(73) Assignee: SEIKO EPSON CORPORATION, Tokyo (JP)

(21) Appl. No.: 12/854,718

(22) Filed: Aug. 11, 2010

(30) Foreign Application Priority Data
Aug. 12, 2009 (JP) 2009-187081

(51) Int. Cl. B41J 2/045; H01L 41/18

(52) U.S. Cl. 347/68; 310/365

(57) ABSTRACT

A liquid ejecting head includes a passage-forming substrate provided with a pressure-generating chamber communicated with a nozzle which ejects droplets, and a piezoelectric element provided on the passage-forming substrate. The piezoelectric element includes a piezoelectric layer and a pair of electrodes provided on both surfaces of the piezoelectric layer, and the piezoelectric layer contains BaTiO₃, CaTiO₃, and (Bi_{1/2}Na_{1/2})TiO₃.

### CROSS-REFERENCE TO RELATED APPLICATIONS

This application claims the benefit of priority to Japanese Patent Application No. 2009-187081 filed Aug. 12, 2009, the contents of which are hereby incorporated by reference in their entirety.

### BACKGROUND

1. Technical Field

The present invention relates to a liquid ejecting head which ejects droplets from a nozzle by producing pressure fluctuation in a pressure-generating chamber due to displacement of a piezoelectric element and relates to a liquid ejecting apparatus using the liquid ejecting head.

2. Related Art

A typical example of liquid ejecting heads is an ink jet recording head including a vibrating plate which constitutes a portion of a pressure-generating chamber communicated with a nozzle which ejects ink droplets so that the vibrating plate is deformed by a piezoelectric element to apply pressure to ink in the pressure-generating chamber, ejecting the ink as ink droplets from the nozzle. An example of the piezoelectric element used in the ink jet recording head includes a piezoelectric layer interposed between two electrodes and composed of a piezoelectric material exhibiting an electro-mechanical conversion function, for example, a crystallized dielectric material. As the piezoelectric material used for such a piezoelectric element, lead-based piezoelectric ceramics, such as lead zirconate titanate (PZT), is generally used (refer to, for example, Japanese Unexamined Patent Application Publication No. 2001-223404).

However, lead-based waste adversely affects the environment by elution of lead when exposed to acid rain or the like. Therefore, use of a lead-free piezoelectric material as an alternative to PZT is desired for a piezoelectric element. For example, a piezoelectric element using barium titanate (BaTiO₃) as a lead-free piezoelectric material has been proposed (refer to, for example, Japanese Unexamined Patent Application Publication No. 2000-72539).

In addition, the characteristics of the piezoelectric layer are not sufficient for use in the piezoelectric element of the liquid ejecting head, and thus further improvement is demanded. Therefore, for example, it has been proposed to improve voltage endurance by adding calcium titanate (CaTiO₃) to barium titanate (BaTiO₃) (refer to, for example, Japanese Unexamined Patent Application Publication No. 6-279110).

However, the barium titanate-based piezoelectric material has a low Curie point and thus when the piezoelectric material is used for the piezoelectric element, sufficient piezoelectric characteristics may not be obtained even by adding CaTiO₃ to BaTiO₃. Specifically, the barium titanate-based piezoelectric material has a Curie point of as low as about 130° C. and has a transformation point near room temperature accompanying crystal structure phase transition. Therefore, the piezoelectric element using the barium titanate-based piezoelectric material does not have sufficient temperature characteristics, and, for example, the piezoelectric characteristics may be changed with a temperature change of the piezoelectric element, thereby failing to achieve a stable displacement. As a result, the ejection characteristics of ink droplets may be changed, causing deterioration in print quality and variation in print quality.

Such a problem is not limited to liquid ejecting heads such as the ink jet recording head, but is also present in liquid ejecting heads mounted on other apparatuses.

### SUMMARY

An advantage of some aspects of the invention is that the invention provides a liquid ejecting head environmentally friendly and capable of stably producing good ejection characteristics and also provides a liquid ejecting apparatus using the head.

A liquid ejecting head according to an embodiment of the present invention includes a passage-forming substrate provided with a pressure-generating chamber communicated with a nozzle which ejects droplets, and a piezoelectric element provided on the passage-forming substrate. The piezoelectric element includes a piezoelectric layer and a pair of electrodes provided on both surfaces of the piezoelectric layer, and the piezoelectric layer contains BaTiO₃, CaTiO₃, and (Bi_{1/2}Na_{1/2})TiO₃. In particular, the piezoelectric layer preferably further contains Eu₂O₃.

A liquid ejecting apparatus according to an embodiment of the present invention includes the above-described liquid ejecting head.

According to an embodiment of the present invention, a piezoelectric layer constituting a piezoelectric element does not contain lead and is thus environmentally friendly, and it is possible to improve the voltage endurance characteristics of the piezoelectric element and satisfactorily maintain displacement characteristics, thereby satisfactorily ejecting droplets.

### BRIEF DESCRIPTION OF THE DRAWINGS

The invention will be described with reference to the accompanying drawings, wherein like numbers reference like elements.

FIG. 1 is an exploded perspective view of a recording head according to an embodiment of the present invention.

FIG. 2A is a plan view of a recording head according to an embodiment of the present invention.

FIG. 2B is a sectional view of a recording head according to an embodiment of the present invention.

FIG. 3 is a flowchart showing a method for manufacturing of a piezoelectric element according to an embodiment of the present invention.

FIG. 4 is a schematic perspective view of a liquid ejecting apparatus according to an embodiment of the present invention.

### DESCRIPTION OF EXEMPLARY EMBODIMENTS

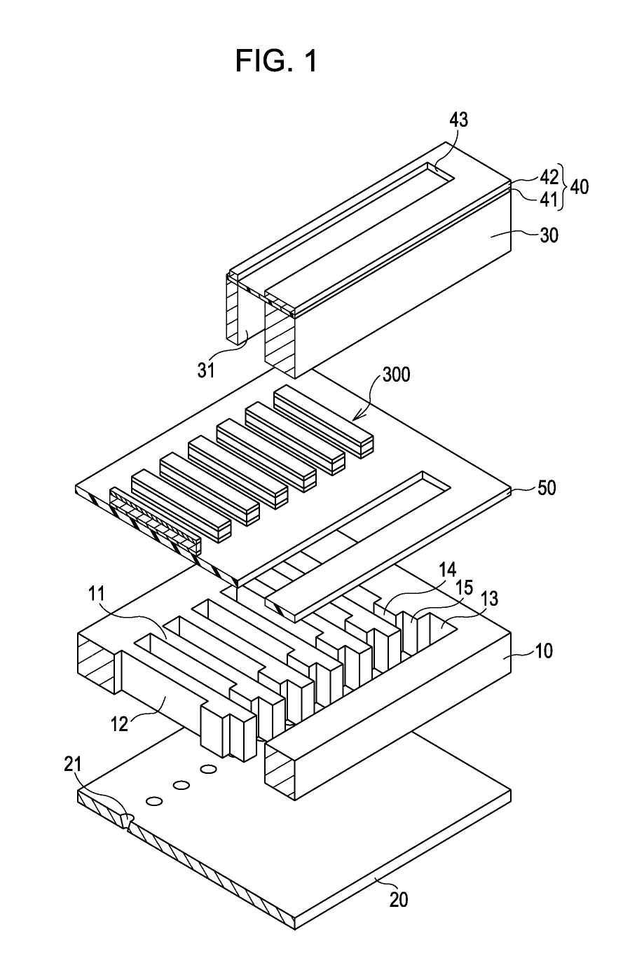

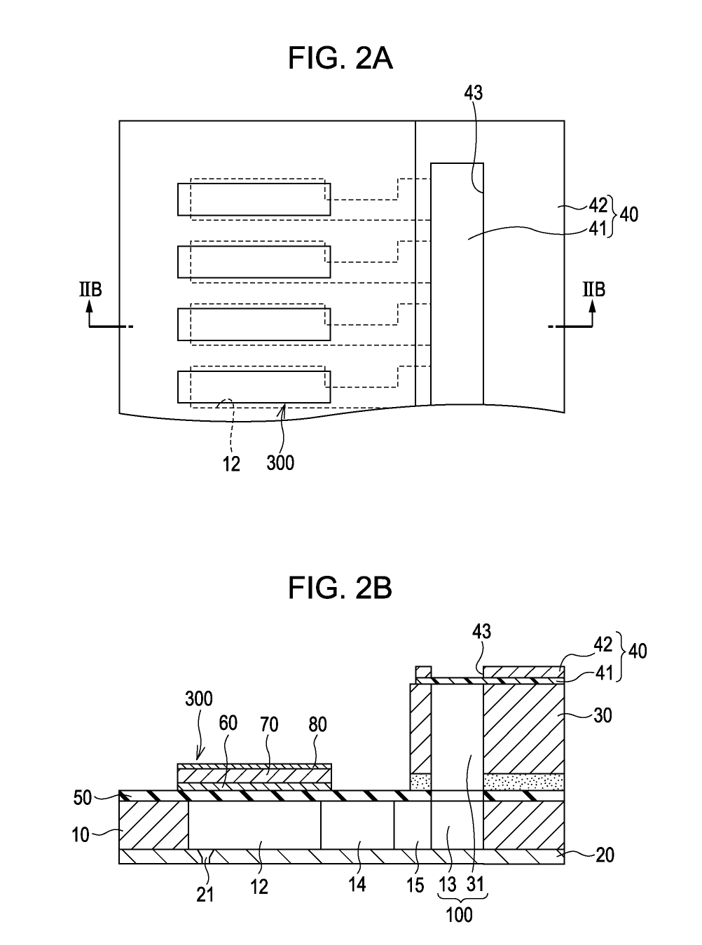

FIG. 1 is an exploded perspective view showing a schematic configuration of an ink jet recording head according to an embodiment of the present invention. FIG. 2A is a plan view and FIG. 2B is a sectional view taken along line IIB-IIB in FIG. 2A.

As shown in FIGS. 1, 2A, and 2B, an ink jet recording head as an example of liquid ejecting heads includes an ink flow passage formed by a plurality of substrates including a passage-forming substrate 10. The passage-forming substrate 10 includes a plurality of pressure-generating chambers 12 partitioned by partition walls 11 and disposed in parallel in the width direction. The passage-forming substrate 10 also includes a communication portion 13 formed in a region outside the pressure-generating chambers 12 in the longitudinal direction so that the communication portion 13 is communicated with the pressure-generating chambers 12 through ink supply passages 14 and communication passages 15 provided for the respective pressure-generating chambers 12. The communication portion 13 is communicated with a reservoir portion of a reservoir-forming substrate described below to form a portion of a reservoir 100 serving an ink chamber common to the pressure-generating chambers 12. The passage-forming substrate 10 includes, for example, a silicon single-crystal substrate having (100) crystal plane orientation.

A nozzle plate 20 is fixed to a surface of the passage-forming substrate 10, in which ink passages are opened, with an adhesive film, a heat-seal film, or the like. The nozzle plate 20 has a plurality of nozzles 21 formed therein and communicated with the vicinities of the ends of the respective pressure-generating chambers 12 on the side opposite to the ink supply passage 14 side. The nozzle plate 20 is composed of, for example, glass ceramic, silicon single-crystal substrate, stainless steel, or the like.

On the other hand, an elastic film 50 composed of an oxide film is formed on a surface of the passage-forming substrate 10 on the side opposite to the nozzle plate 20 side. In addition, a piezoelectric element 300 including a lower electrode film 60, a piezoelectric layer 70, and an upper electrode film 80 is formed on the elastic film 50. In general, one of the electrodes of a piezoelectric element serves as a common electrode common to a plurality of piezoelectric elements, and the other electrode serves as an individual electrode independent for each piezoelectric element. In this embodiment, the lower electrode film 60 corresponds to the common electrode of the piezoelectric elements 300, and the upper electrode film 80 corresponds to the individual electrode. However, these electrode films may be reserved in view of a driving circuit and wiring.

In the present invention, the piezoelectric layer 70 constituting the piezoelectric element 300 is composed of a so-called bulk piezoelectric material containing at least BaTiO₃, CaTiO₃, and (Bi_{1/2}Na_{1/2})TiO₃.

Consequently, the voltage endurance characteristics of the piezoelectric layer are improved. In addition, the Curie point becomes as relatively high as 200° C. or more. Therefore, even when a temperature change occurs in the piezoelectric element 300, the temperature characteristics of the piezoelectric layer 70 are stable, and the displacement characteristics of the piezoelectric element 300 are maintained in good conditions equivalent to or higher than those in the case, for example, using a piezoelectric material such as lead zirconate titanate (PZT) or the like. In other words, ink droplets can be satisfactorily ejected, and the ejection characteristics are uniformed regardless of temperature changes of the piezoelectric element 300.

Specifically, since the piezoelectric layer 70 contains BaTiO₃ and CaTiO₃, the effect of improving the voltage endurance characteristics of the piezoelectric layer 70 is obtained. Further, since the piezoelectric layer 70 contains (Bi_{1/2}Na_{1/2})TiO₃, the effect of improving the temperature characteristics of the piezoelectric layer 70 by increasing the Curie point thereof is obtained. Specifically, the Curie point of the piezoelectric layer 70 is increased to 200° C. or more, and the transformation point accompanying crystal structure phase transition is present near −50° C. For comparison, a BaTiO₃-based piezoelectric material generally has a Curie point of about 130° C. and a transformation point accompanying crystal structure phase transition which is present near 19° C.

In this way, it was proved by experiment that the Curie point is increased. For example, a piezoelectric layer composed of only BaTiO₃ showed a Curie point of 129° C., while when (Bi_{1/2}Na_{1/2})TiO₃ was added to BaTiO₃ at a ratio (BaTiO₃:(Bi_{1/2}Na_{1/2})TiO₃) of 7:3, the Curie point was increased to 210° C. Further, when the ratio was 6:4, the Curie point was increased to 221° C.

In this embodiment, the piezoelectric layer 70 further contains Eu₂O₃. Namely, the piezoelectric layer 70 contains BaTiO₃, CaTiO₃, (Bi_{1/2}Na_{1/2})TiO₃, and Eu₂O₃.

Therefore, the voltage endurance characteristics and the temperature characteristics of the piezoelectric layer 70 are improved, and the piezoelectric characteristics are maintained in good conditions. Therefore, ink droplets can be satisfactorily ejected, and the ejection characteristics can be uniformed regardless of temperature changes of the piezoelectric element 300.

Further, since the piezoelectric layer 70 is made of a lead-free piezoelectric material as described above, the adverse effect on the environment can also be prevented.

Although, in this embodiment, the piezoelectric layer contains Eu₂O₃, Eu₂O₃ may be not necessarily contained, and the piezoelectric layer may contain at least BaTiO₃, (Bi_{1/2}Na_{1/2})TiO₃, and CaTiO₃.

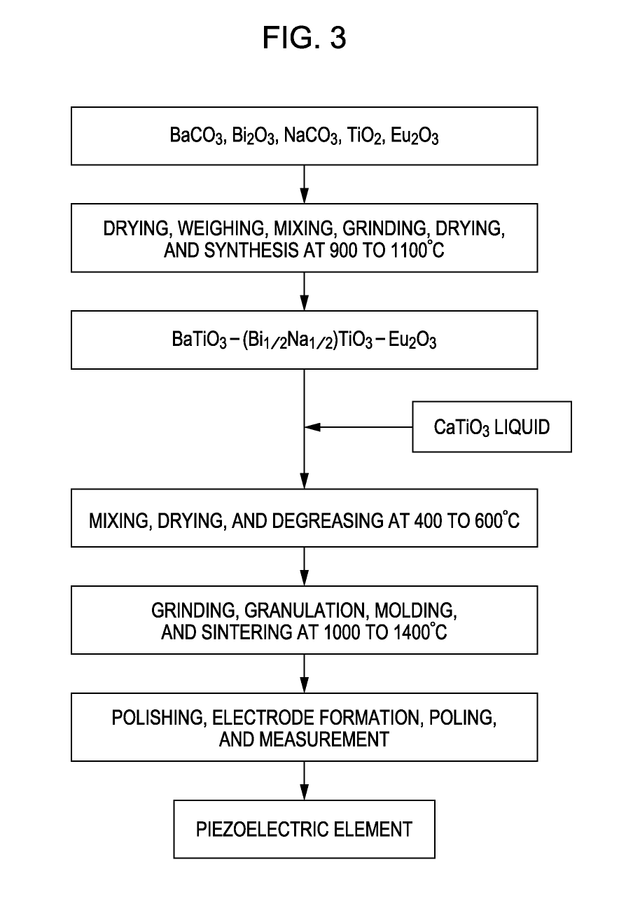

Here, an example of a method for manufacturing the piezoelectric element 300 is described with reference to FIG. 3. FIG. 3 is a flowchart showing a method for manufacturing a piezoelectric element.

As shown in FIG. 3, first, for example, powders of BaCO₃, Bi₂O₃, NaCO₃, TiO₂, and Eu₂O₃ are prepared as starting materials of main components for forming the piezoelectric layer 70 and weighed at a predetermined ratio in a dry state. Then, for example, pure water, ethanol, or the like is added to the powders, and the mixture is mixed and ground with a ball mill to prepare a raw material mixture. Further, the raw material mixture is dried and then synthesized (calcined) at, for example, 900° C. to 1100° C. to form a powder containing BaTiO₃, (Bi_{1/2}Na_{1/2})TiO₃, and Eu₂O₃.

Next, a CaTiO₃ liquid (sol-gel liquid) is added to the powder and mixed by a ball mill or the like, and the mixture is dried and then degreased at a temperature of about 400° C. to 600° C. Next, the degreased powder is ground, and a predetermined amount of a binder is added to the resultant powder. Then, the mixture is granulated and then molded by a mold press or the like under a predetermined pressure. The molded product is sintered at a temperature of about 1000° C. to 1400° C. to form a so-called bulk piezoelectric material containing BaTiO₃, CaTiO₃, (Bi_{1/2}Na_{1/2})TiO₃, and Eu₂O₃.

Then, the piezoelectric material is polished, and an electrode is formed on a surface thereof. Further, poling and various measurements are performed to form the above-described piezoelectric element 300. Namely, when the piezoelectric element 300 is formed by the above-described method, an ink jet recording head environmentally friendly and capable of satisfactorily ejecting ink droplets regardless of temperature changes can be realized.

In particular, in this embodiment, the CaTiO₃ liquid is added to the powder containing BaTiO₃, (Bi_{1/2}Na_{1/2})TiO₃, and Eu₂O₃. In other words, a solid phase method and a liquid phase method are combined so that the CaTiO₃ liquid is added during the preparation of the piezoelectric material. Therefore, the voltage endurance characteristics and the piezoelectric characteristics of the piezoelectric layer 70 can be more securely improved. Of course, CaTiO₃ may be added in a powder state as a starting material.

Returning to the description of the head structure, a reservoir-forming substrate 30 is bonded to the passage-forming substrate 10 on which the piezoelectric element 30 is formed, the reservoir-forming substrate 30 being provided with the reservoir portion 31 communicated with the communication portion 13. In this embodiment, the reservoir portion 31 is formed to extend over the pressure-generating chambers 12 in the width direction so as to pass through the reservoir-forming substrate 30 in the thickness direction. As described above, the reservoir portion 31 is communicated with the communication portion 13 of the passage-forming substrate 10 to form the reservoir 100 serving as an ink chamber common to the pressure-generating chambers 12.

For the reservoir-forming substrate 30, a material having substantially the same thermal expansion coefficient as the passage-forming substrate 10, for example, glass, a ceramic material, or the like, is preferably used. In this embodiment, a silicon single-crystal substrate composed of the same material as the passage-forming substrate 10 is used.

In addition, a compliance substrate 40 including a sealing film 41 and a fixing plate 42 is bonded to the reservoir-forming substrate 30. The sealing film 41 is composed of a material having low rigidity and flexibility, and one of the sides of the reservoir portion 31 is sealed with the sealing film 41. The fixing plate 42 is made of a relatively hard material. The fixing plate 42 has an opening 43 formed by completely removing a region facing the reservoir 100 in the thickness direction. Therefore, one of the sides of the reservoir 100 is sealed with only the sealing film 41 with flexibility.

In the ink jet recording head according to this embodiment, an ink is introduced through an ink inlet connected to an outside ink supply unit (not shown) so that the inside ranging from the reservoir 100 to the nozzles 21 is filled with the ink. Then, flexural deformation is produced by applying a voltage to the piezoelectric element 300 corresponding to each of the pressure-generating chambers 12 according to a recording signal input from a driving circuit (not shown). As a result, the pressure in each of the pressure-generating chambers 12 is increased to eject ink droplets from the nozzles 21.

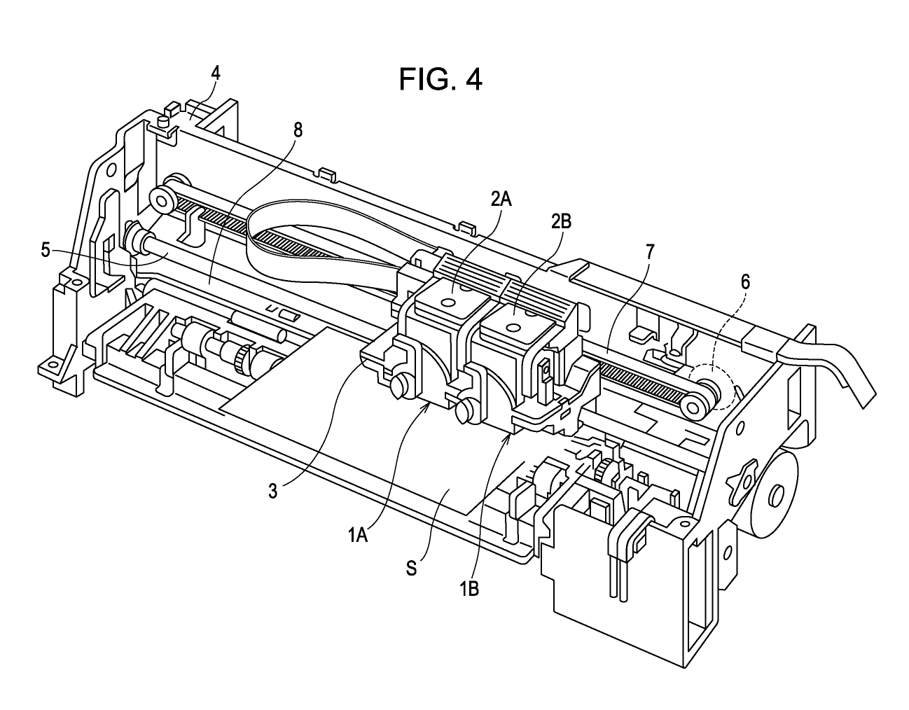

The ink jet recording head is mounted on an ink jet recording apparatus so as to constitute a portion of a recording head unit having an ink passage communicated with an ink cartridge or the like. FIG. 4 is a schematic view showing an example of the ink jet recording apparatus.

As shown in FIG. 4, recording head units 1A and 1B each having an ink jet recording head include cartridges 2A and 2B, respectively, which constitute the ink supply unit and are detachably provided. A carriage 3 provided with the recording head units 1A and 1B is provided on a carriage shaft 5 attached to an apparatus body 4 so that the carriage 3 can be moved in the axial direction. The recording head units 1A and 1B are adapted for, for example, ejecting a black ink composition and a color ink composition, respectively.

When the driving force of a driving motor 6 is transmitted to the carriage 3 through a plurality of gears (not shown) and a timing belt 7, the carriage 3 provided with the recording head units 1A and 1B is moved along the carriage shaft 5. On the other hand, a platen 8 is provided along the carriage shaft 5 of the apparatus body 4 so that a recording sheet S serving as a recording medium, such as paper or the like, which is supplied by a feed roller or the like (not shown), is transported by winding on the platen 8.

Although, in the embodiment, the ink jet recording head is described as an example of the liquid ejecting head, the present invention is widely aimed at liquid ejecting heads in general and, of course, can be applied to a liquid ejecting head which ejects a liquid other than ink. Examples of other liquid ejecting heads include various recording heads used for image recording apparatuses such as a printer and the like, colorant ejecting heads used for producing color filters of a liquid crystal display and the like, electrode material ejecting heads used for forming electrodes of an organic EL display, FED (field emission display), and the like, bio-organic ejecting heads used for producing bio-chips, and the like.

What is claimed is:

1. A piezoelectric element comprising a piezoelectric layer and a pair of electrodes, wherein the piezoelectric layer contains BaTiO₃, CaTiO₃, and (Bi_{1/2}Na_{1/2})TiO₃.

2. The piezoelectric element according to claim 1, wherein the piezoelectric layer further contains Eu₂O₃.

3. A liquid ejecting head comprising the piezoelectric element according to claim 1.

4. A liquid ejecting apparatus comprising the liquid ejecting head according to claim 3.
